(19) United States
(12) Patent Application Publication
(10) Pub. No.: US 2025/0294728 A1
(43) Pub. Date: Sep. 18, 2025

(54) SEMICONDUCTOR DEVICES AND FABRICATING METHODS THEREOF

(71) Applicant: YANGTZE MEMORY TECHNOLOGIES CO., LTD., Wuhan (CN)

(72) Inventors: Wei XU, Wuhan (CN); Wei LIU, Wuhan (CN); Jianlu WANG, Wuhan (CN); Beibei LI, Wuhan (CN); Zongliang HUO, Wuhan (CN)

(21) Appl. No.: 18/623,389

(22) Filed: Apr. 1, 2024

Related U.S. Application Data
(63) Continuation of application No. PCT/CN2024/081702, filed on Mar. 14, 2024.

(51) Int. Cl. H10B 12/00

(52) U.S. Cl. CPC H10B 12/488; H10B 12/05; H10B 12/315

(57) ABSTRACT

Three-dimensional (3D) memory devices and fabricating methods are provided. In some implementations, a disclosed semiconductor device is a memory device and comprises an array of memory cells in an array region, word lines extending parallel in a first lateral direction, bit lines extending parallel in a second lateral direction, and interconnection structures located within the array region and coupled with the word lines, and arranged in staggered columns along the second lateral direction.

### CROSS-REFERENCE TO RELATED APPLICATIONS

This application is a continuation of International Application No. PCT/CN2024/081702, filed on Mar. 14, 2024, entitled “SEMICONDUCTOR DEVICES AND FABRICATING METHODS THEREOF,” which is incorporated herein by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

One aspect of the present disclosure provides a memory device, comprising: an array of memory cells in an array region; word lines extending parallel in a first lateral direction; bit lines extending parallel in a second lateral direction; and interconnection structures located within the array region and coupled with the word lines, and arranged in staggered columns along the second lateral direction.

In some implementations, a first distance between two interconnection structures coupled with two adjacent word lines is greater than a second distance between the two adjacent word lines.

In some implementations, a first column of interconnection structures are located at a first side of a center position of the array region; and a second column of interconnection structures are located at a second side of the center position opposite to the first side.

In some implementations, a first column of interconnection structures are located at a first side of one bit line; and a second column of interconnection structures are located at a second side of the one bit line opposite to the first side.

In some implementations, a third distance between the first column of interconnection structures and the center position is equal to a fourth distance between the second column of interconnection structures and the center position.

In some implementations, a third distance between the first column of interconnection structures and the center position is different from a fourth distance between the second column of interconnection structures and the center position.

In some implementations, a first column of interconnection structures and a second column of interconnection structures are located at a same side of a center position of the array region.

In some implementations, the memory device further comprises: a conductive layer connected to first ends of the interconnection structures, wherein second ends of the interconnection structures are connected to the word lines.

In some implementations, the interconnection structures comprise rows of interconnection structures aligned parallel along the first lateral direction; and the interconnection structures in a same row are connected to a same word line.

In some implementations, the memory device further comprises: a first conductive layer connected to odd numbers of rows of interconnection structures; and a second conductive layer connected to even numbers of rows of interconnection structures.

In some implementations, each of the array of memory cells comprises a vertical transistor and a storage unit coupled with the vertical transistor; and each word line comprises gate structures of a corresponding row of vertical transistors aligned along the first lateral direction.

In some implementations, in each vertical transistor, a gate structure is located at a lateral side of a channel structure of the vertical transistor.

In some implementations, in each vertical transistor, the gate structure is located at three lateral sides of the channel structure of the vertical transistor.

In some implementations, in each vertical transistor, the gate structure laterally surrounds the channel structure of the vertical transistor.

Another aspect of the present disclosure provides a method of forming a memory device, comprising: forming bit lines extending parallel in a second lateral direction on a semiconductor layer; forming an array of vertical transistors, comprising: forming an array of vertical channel structures, each column of the vertical channel structures along the second lateral direction are coupled with a corresponding one of the bit lines, and forming gates structures at a lateral side of each row of the vertical channel structures along a first lateral direction, wherein the gates structures of each column of the array of vertical transistors form one word line along the first lateral direction; forming interconnection structures each vertically extending through the semiconductor layer and in contact with a corresponding word line; removing the semiconductor layer to expose portions of the interconnection structures; and forming a conductive layer coupled with the interconnection structures.

In some implementations, forming the interconnection structures comprises forming columns of interconnection structures aligned parallel along the second lateral direction; and adjacent columns of interconnection structures are arranged in a staggered form.

In some implementations, forming the interconnection structures comprises forming rows of interconnection structures aligned parallel along the first lateral direction; and the interconnection structures in a same row are connected to a same word line, and adjacent rows of interconnection structures are arranged in a staggered form.

In some implementations, forming the conductive layer comprises: forming a first conductive layer connected to odd numbers of rows of interconnection structures; and forming a second conductive layer connected to even numbers of rows of interconnection structures.

In some implementations, the method further comprises: forming an array of storage units on the array of vertical transistors.

Another aspect of the present disclosure provides a method of forming a memory device, comprising: forming an array of semiconductor pillars on a semiconductor layer; forming an insulating layer on the semiconductor layer to laterally isolate the semiconductor pillars; forming sacrificial structures each vertically extending through the insulating layer and into the semiconductor layer; forming conductive lines each at a lateral side of each row of the semiconductor pillars along a first lateral direction, wherein the conductive lines are in contact with the sacrificial structures; removing the semiconductor layer to expose portions of the sacrificial structures; replacing the sacrificial structures with interconnection structures; and forming a conductive layer coupled with the interconnection structures.

In some implementations, forming the sacrificial structures comprises forming columns of sacrificial structures aligned parallel along a second lateral direction; and adjacent columns of sacrificial structures are arranged in a staggered form.

In some implementations, forming the sacrificial structures comprises forming rows of sacrificial structures aligned parallel along the first lateral direction; and the sacrificial structures in a same row are connected to a same conductive line, and adjacent rows of sacrificial structures are arranged in a staggered form.

In some implementations, forming the conductive layer comprises: forming a first conductive layer connected to odd numbers of rows of interconnection structures; and forming a second conductive layer connected to even numbers of rows of interconnection structures.

In some implementations, the method further comprises: forming bit lines and extending parallel in the second lateral direction and coupled with second ends of the array of semiconductor pillars; and forming an array of storage units coupled with second ends of the array of semiconductor pillars.

In some implementations, forming the conductive structure comprises: forming the conductive structure to laterally surround each channel structure in the row.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a memory device including an array of memory cells each having a vertical transistor, according to some implementations of the present disclosure.

FIG. 2A illustrates a schematic plan view of a memory device, according to some implementations of the present disclosure.

FIG. 2B illustrates a schematic plan view of a memory device, according to some implementations of the present disclosure.

FIG. 3A illustrates a schematic plan view of a portion of a memory device, according to some implementations of the present disclosure.

FIG. 3B illustrates a schematic side cross-sectional view of a cross-section of a portion of a memory device, according to some implementations of the present disclosure.

FIG. 3C illustrates a schematic side cross-sectional view of a cross-section of a portion of a memory device, according to some implementations of the present disclosure.

FIG. 4A illustrates a schematic plan view of a portion of a memory device, according to some implementations of the present disclosure.

FIG. 4B illustrates a schematic side cross-sectional view of a cross-section of a portion of a memory device, according to some implementations of the present disclosure.

FIG. 4C illustrates a schematic side cross-sectional view of a cross-section of a portion of a memory device, according to some implementations of the present disclosure.

FIG. 5A illustrates a schematic plan view of a portion of a memory device, according to some implementations of the present disclosure.

FIG. 5B illustrates a schematic side cross-sectional view of a cross-section of a portion of a memory device, according to some implementations of the present disclosure.

FIG. 5C illustrates a schematic side cross-sectional view of a cross-section of a portion of a memory device, according to some implementations of the present disclosure.

FIG. 6A illustrates a schematic plan view of a portion of a memory device, according to some implementations of the present disclosure.

FIG. 6B illustrates a schematic side cross-sectional view of a cross-section of a portion of a memory device, according to some implementations of the present disclosure.

FIG. 6C illustrates a schematic side cross-sectional view of a cross-section of a portion of a memory device, according to some implementations of the present disclosure.

FIG. 7 illustrates a block diagram of a system having a memory device, according to some implementations of the present disclosure.

FIG. 8 illustrates a flowchart of a fabricating method for forming a 3D memory device, according to some implementations of the present disclosure.

FIGS. 9A-9E each illustrates a schematic side cross-sectional view of a 3D memory device at a certain fabricating stage of the method shown in FIG. 8, according to various implementations of the present disclosure.

FIG. 10 illustrates a flowchart of a fabricating method for forming a 3D memory device, according to some implementations of the present disclosure.

FIGS. 11A-11B, 12A-12B, 13 and 14 each illustrates a schematic side cross-sectional view of a 3D memory device at a certain fabricating stage of the method shown in FIG. 10, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features, as described in the present disclosures, can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as dynamic radon access memory (DRAM). In a one-transistor-one-capacitor (1T1C) DRAM structure, the data are stored in the capacitors. In traditional DRAM architectures, the word lines (WL) are usually buried at one or more sides of the channel structure of transistors, which causes significant WL-WL parasitic capacitance. Further, the WL routing interconnections in contact with the word lines are generally located on both sides of the array. The Back-End-of-Line (BEOL) routing also contributes significantly to the parasitic capacitance. To meet the sense margin requirements, the capacitors require a substantial large capacitance, posing significant challenges in terms of process difficulty, and increasing difficulty to further shrinkage with the continuous scaling development of DRAM.

To address one or more of the aforementioned issues, the present disclosure introduces a solution in which a pre-buried WL method is applied. Specifically, in some implementations, periodic metal vias can be embedded during the Front-End-of-Line (FEOL) process. In some other implementations, periodic sacrificial vias can be embedded during the FEOL process, and then be replaced with metal in a subsequent process. In the BEOL process, the metal vias of adjacent two word lines can be routed out alternately through a metal line layer. In some implementations, two or more layers of metal lines may be applied for forming the word line interconnection structures to further reduce the parasitic capacitance. By completing the vias in the FEOL process, overlay (OVL) issues in the BEOL process can be avoided, enabling the interconnection pickup of a grid-like layout of word lines. The disclosed solution can significantly reduce the WL-WL parasitic capacitance, thereby lowering the capacitance requirements for the capacitors, reducing the difficulty of capacitor fabrication, and opening up pathways for further shrinkage with the continuous scaling development of DRAM.

Consistent with the scope of the present disclosure, according to some implementations of the present disclosure, the memory cell array having vertical transistors, each including a semiconductor layer extending in a vertical direction, and a gate structure beside the semiconductor layer or surrounded by the semiconductor layer. In some implementations, the word lines and bit lines connected to the vertical transistors are arranged along a first lateral direction and a second lateral direction, respectively. Each of the semiconductor bodies of the array of vertical transistors extends along a vertical direction. By using such an arrangement, memory area efficiency can be increased. Further, the memory cell array and the peripheral circuits can be formed separately on different wafers, such that the fabricating processes of the memory cell array and the peripheral circuits do not affect each other, and the memory area efficiency can be further increased.

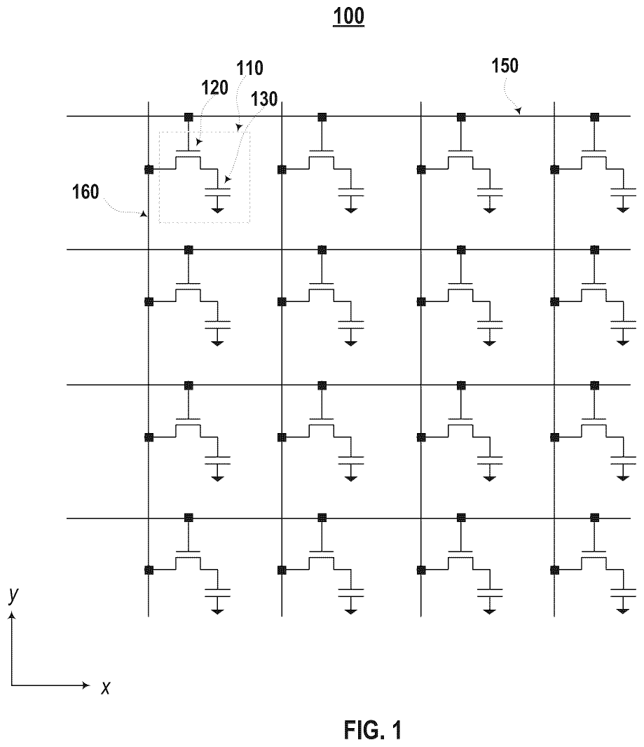

FIG. 1 illustrates a schematic diagram of a memory device 100 having an array of memory cells, each having a vertical transistor, according to some implementations of the present disclosure. Memory device 100 can include a memory cell array in which each memory cell 110 includes a vertical transistor 120 and a storage unit coupled to vertical transistor 120. In some implementations as shown in FIG. 1, the memory cell array is a DRAM cell array, and the storage unit is a capacitor 130 for storing charge as the binary information stored by the respective DRAM cell. In some other implementations not shown in the figures, the memory cell array is a PCM cell array, and the storage unit can be a PCM element (e.g., including chalcogenide alloys) for storing binary information of the respective PCM cell based on the different resistivities of the PCM element in the amorphous phase and the crystalline phase.

As shown in FIG. 1, memory cells 110 can be arranged in a two-dimensional (2D) array having rows and columns. Memory device 100 can include word lines 150 coupling the memory cell array to peripheral circuits for controlling the switch of vertical transistors 120 in memory cells 110 located in a row, as well as bit lines 160 coupling the memory cell array to peripheral circuits for sending data to and/or receiving data from memory cells 110 located in a column. That is, each word line 150 is coupled to a respective row of memory cells 110, and each bit line 160 is coupled to one or more respective logic columns of memory cells 110. In some implementations, the gate of vertical transistor 120 is coupled to word line 150, one of the source and the drain of vertical transistor 120 is coupled to bit line 160, the other one of the source and the drain of vertical transistor 120 is coupled to one electrode of capacitor 130, and the other electrode of capacitor 130 is coupled to the ground.

Consistent with the scope of the present disclosure, vertical transistors 120, such as vertical metal-oxide-semiconductor field-effect transistors (MOSFETs), can replace the conventional planar transistors as the pass transistors of memory cells 110 to reduce the area occupied by the pass transistors, the coupling capacitance, as well as the interconnect routing complexity, as described below in detail.

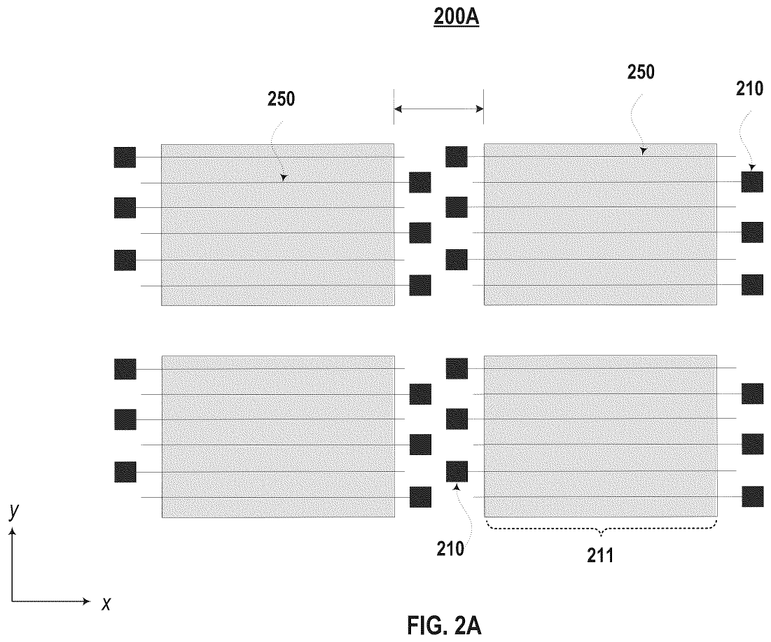

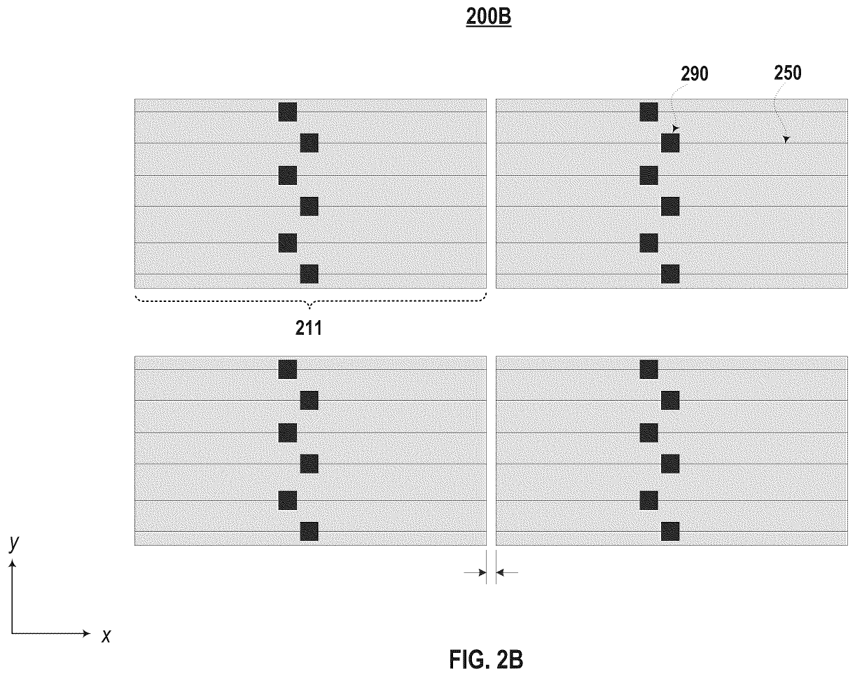

FIG. 2A illustrates a schematic plan view of a memory device 200A comprising a plurality of memory arrays 211 in the x-y plane, according to some implementations of the present disclosure. Each memory array 211 can include an array of memory cells each including a vertical transistor and a vertical capacitor. The vertical transistor can have any suitable arrangement of the components, according to some implementations of the present disclosure, such as a channel-all-around (CAA) type vertical transistor, a gate-all-around type vertical transistor, a single-metal-gate (SMG) type vertical transistor, a double-metal-gate (DMG) type vertical transistor, a triple-metal-gate (TMG) type vertical transistor, etc.

As shown in FIG. 2A, each memory array 211 can include a plurality of word lines 250 each extending in a first lateral direction (the x-direction, referred to as the word line direction). It is noted that, each memory array 211 can further include a plurality of bit lines (not shown) each extending in a second lateral direction (the y-direction, referred to as the bit line direction) perpendicular to the first lateral direction. The word lines 250 and bit lines may be formed in different lateral planes for ease of routing. In some implementations, memory device 200A can further comprise a plurality of word line interconnection structures 210 located at both sides of each memory array 211 along the word line direction (the x-direction). The word lines 250 can be interconnected to the word line interconnection structures 210 in a staggered manner at both sides of each memory array 211 along the word line direction (the x-direction). For example, a first group of word line interconnection structures 210 located at a first side of each memory array 211 can be connected to the odd numbers of word lines 250, and a second group of word line interconnection structures 210 located at a second side of each memory array 211 can be connected to the even numbers of word lines 250.

Such layout may require a relatively large space between adjacent memory arrays 211 to locate the word line interconnection structures 210. For example, the region between adjacent memory arrays 211 for locating the word line interconnection structures 210 can occupy approximately 4.6% of the total area of the memory device, making it difficult to downsize the memory arrays 211, because this proportion increases when downsizing the memory arrays 211. Further, due to the word lines 250 being driven via the word line interconnection structures 210 on both ends, the lead-out resistance of the word lines 250 can be relatively high, resulting in substantial resistive-capacitive (RC) delay. Additionally, the wiring of the word line driving wires contributes significantly to parasitic capacitance due to being driven on both ends.

FIG. 2B illustrates a schematic plan view of a memory device 200B comprising a plurality of memory arrays 211 in the x-y plane, according to some implementations of the present disclosure. Each memory array 211 can include an array of memory cells each including a vertical transistor and a vertical capacitor. The vertical transistor can have any suitable arrangement of the components, according to some implementations of the present disclosure, such as a channel-all-around (CAA) type vertical transistor, a gate-all-around type vertical transistor, a single-metal-gate (SMG) type vertical transistor, a double-metal-gate (DMG) type vertical transistor, a triple-metal-gate (TMG) type vertical transistor, etc.

As shown in FIG. 2B, each memory array 211 can include a plurality of word lines 250 each extending in the first lateral direction (the x-direction). It is noted that, each memory array 211 can further include a plurality of bit lines (not shown) each extending in the second lateral direction (the y-direction). The word lines 250 and bit lines may be formed in different lateral planes for ease of routing. In some implementations, memory device 200B can further comprise a plurality of word line interconnection structures 290 located within the array region and coupled with the word lines 250, and arranged in staggered columns along the second lateral direction (the y-direction). The word lines 250 can be interconnected to the corresponding word line interconnection structures 290 in a staggered manner. For example, a first column of word line interconnection structures 290 aligned along the second lateral direction can be connected to the odd numbers of word lines 250, respectively, while a second column of word line interconnection structures 290 aligned along the second lateral direction can be connected to the even numbers of word lines 250, respectively, as shown in FIG. 2B.

Such a layout does not require a relatively large space between adjacent memory arrays 211 to locate the word line interconnection structures 290. For example, the region between adjacent memory arrays 211 along the first lateral direction can occupy approximately 0.25% or less of the total area of the memory device, making it easy to downsize the memory arrays 211 to decrease capacitance. Further, due to the word lines 250 are driven via the word line interconnection structures 290 from the center of the memory array 211, the routing resistance of the word lines 250 can be relatively low, resulting in a reduced RC delay.

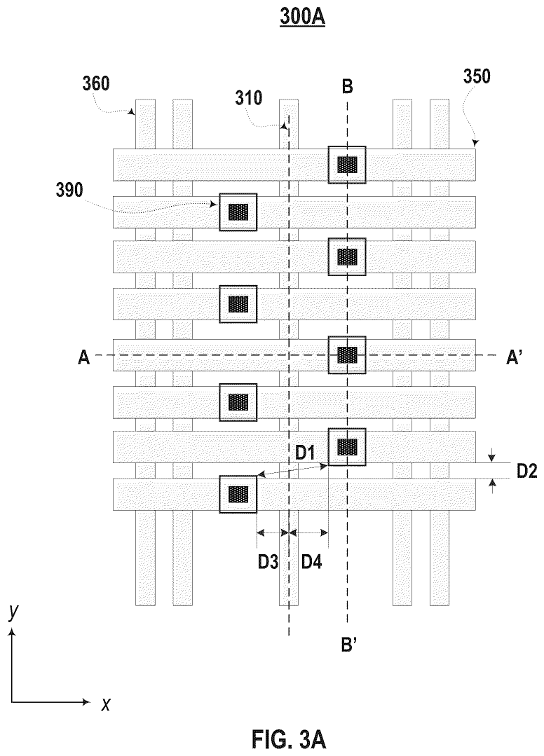

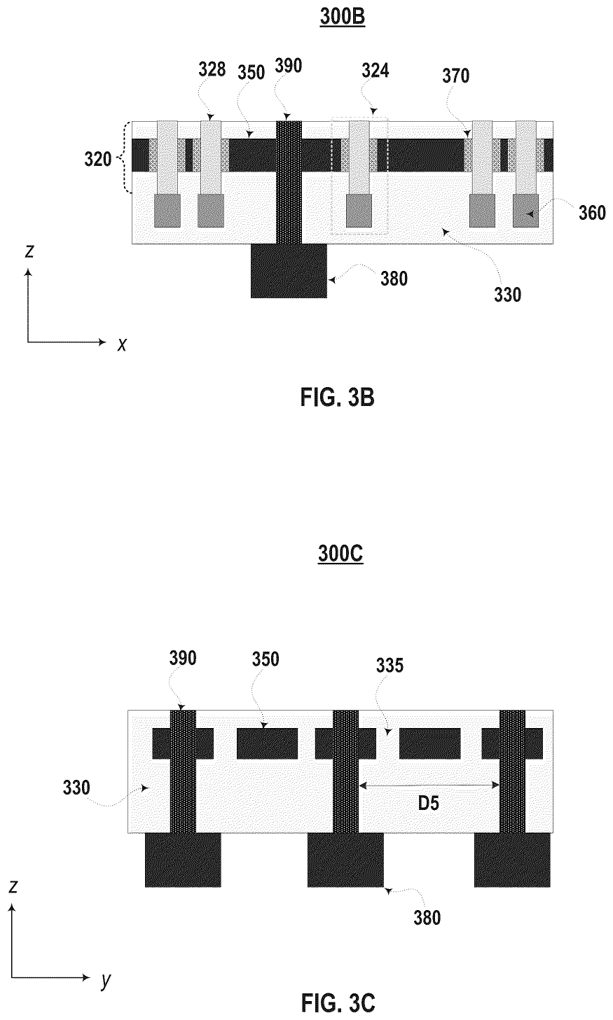

FIG. 3A illustrates a schematic plan view of a memory array 300A in the x-y plane, according to some implementations of the present disclosure. As shown in FIG. 3A, a plurality of word lines 350 extend in parallel along the first lateral direction (the x-direction), and a plurality of bit lines 360 extend in parallel along the second lateral direction (the y-direction). The word lines 350 and bit lines 360 may be formed in different lateral planes for ease of routing. In some implementations, memory array 300A further comprises a plurality of word line interconnection structures 390 located within the array region and coupled with the word lines 350, and arranged in staggered columns along the second lateral direction (the y-direction). The word lines 350 can be interconnected to the corresponding word line interconnection structures 390 in a staggered manner.

In some implementations, a first distance D1 between two word line interconnection structures 390 coupled with two adjacent word lines 350 is greater than a second distance D2 between the two adjacent word lines 350, as shown in FIG. 3A. In some implementations, a first column of word line interconnection structures 390 aligned along the second lateral direction can be connected to the even numbers of word lines 350, respectively, while a second column of word line interconnection structures 390 aligned along the second lateral direction can be connected to the odd numbers of word lines 350, respectively.

As shown in FIG. 3A, the first column of word line interconnection structures 390 can be located at a first side of a center line 310 of the array region of memory array 300A, and the second column of word line interconnection structures 390 can be located at a second side of the center line 310 of the array region of memory array 300A opposite to the first side. In some implementations, a third distance D3 between the first column of word line interconnection structures 390 and the center line 310 is equal to a fourth distance D4 between the second column of word line interconnection structures 390 and the center line 310. In some other implementations, the third distance D3 between the first column of word line interconnection structures 390 and the center line 310 is different from the fourth distance D4 between the second column of word line interconnection structures 390 and the center line 310. In some other implementations not shown in the figures, the first column of word line interconnection structures 390 and the second column of word line interconnection structures 390 can be located at the same side of a center line 310 of the array region of memory array 300A. In some implementations as shown in FIG. 3A, the first column of word line interconnection structures 390 can be located at a first side of one bit line 360, and the second column of word line interconnection structures 390 can be located at a second side of the one bit line 360 opposite to the first side.

FIG. 3B illustrates a schematic side cross-sectional view 300B in the x-z plane of memory array 300A along AA′ line shown in FIG. 3A, according to some implementations of the present disclosure. FIG. 3C illustrates a schematic side cross-sectional view 300C in the y-z plane of memory array 300A along BB′ line shown in FIG. 3A, according to some implementations of the present disclosure.

As shown in FIG. 3B, a transistor layer 320 includes a plurality of vertical transistors 324 each having a vertical semiconductor body 328 and a gate electrode 350 (also referred as word line 350) at one or more lateral sides of vertical semiconductor body 328. Vertical semiconductor body 328 can include any suitable semiconductor material, such as polycrystalline silicon. Vertical semiconductor body 328 can have a leakage value lower than a pico-ampere. In some implementations, the leakage value of vertical semiconductor body 328 is lower than the intrinsic leakage value of monocrystalline silicon. In some implementations, a material of vertical semiconductor body 328 can be a metal oxide semiconductor material, such as IGZO. In some implementations, bit line 360 is in contact with lower ends of semiconductor body 328. In some implementations, word line interconnection structure 390 can extend through bit line 360 and into semiconductor body 328 of transistor layer 320.

In some implementations, gate electrode 350 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 350 may include doped polysilicon, i.e., gate poly. In some implementations, gate electrode 350 includes multiple conductive layers, such as a W layer over a TiN layer. In some implementations, a gate dielectric layer 370 can be located between the vertical semiconductor body 328 and the gate electrode 350. The gate dielectric layer 370 can include any suitable dielectric materials, such as silicon oxide, silicon nitride, silicon oxynitride, or high-k dielectrics. In various implementations, gate electrode 350 can be located at one or more lateral sides of vertical semiconductor body 328 to form CAA type, SMG type, DMG type, or TMG type vertical transistor 324. In some implementations, gate electrodes 350 of a row of vertical transistors 324 along the first lateral direction (the x-direction) can be connected with each other to form word line 350.

As shown in FIGS. 3B and 3C, in some implementations, word line interconnection structures 390 can extend into and/or penetrate through word lines 350 to increase the contact area for better contact conductivity. Word line interconnection structures 390 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. In some implementations, word line interconnection structures 490 can include multiple conductive layers, such as a W layer over a TiN layer. In some implementations, a conductive layer 380 (e.g., a BEOL metal layer) can be connected to lower ends of word line interconnection structures 390.

As shown in FIG. 3C, a column of word line interconnection structures 390 along the second lateral direction (the y-direction) can be alternatively connected between corresponding even/odd number word lines 350 and the conductive layer 380. In some implementations, a fifth distance D5 between adjacent word line interconnection structures 390 in a same column is in a range between about 60 nm and about 120 nm, such as approximately 90 nm. Such pitch distance can meet the overlay requirement for routing in BEOL metal layer 380.

In some implementations, adjacent word lines 350 can be separated from each other by a spacer layer 335 including any suitable dielectric materials including, but not limited to, silicon oxide, silicon nitride, silicon oxynitride, low-k dielectrics, or any combination thereof, and/or with one or more air gaps (not shown). The one or more air gaps may be formed due to the relatively small pitches between adjacent word lines 350. Further, the relatively large dielectric constant of air in air gaps (e.g., about 4 times the dielectric constant of silicon oxide) can improve the insulation effect between adjacent word lines 350. In some implementations, spacer layer 335 is a part of insulating layer 330 covering vertical transistors 324, word lines 350, bit lines 360, word line interconnection structures 390. Word line interconnection structures 390 vertically extend through insulating layer 330 to connect bit lines 360 to conductive layer 380.

In some implementations but not shown in the figures, each memory cell of the memory array 300A in the disclosed memory device can further include a storage unit coupled with the vertical transistor 324. The storage unit can include any devices that can store binary data (e.g., 0 and 1), including but not limited to, capacitors for DRAM cells, and PCM elements for PCM cells. In some implementations, each vertical transistor controls the selection and/or the state switch of the respective storage unit coupled to the vertical transistor 324. In some implementations, the storage unit includes a capacitor. It is understood that the capacitor may include any suitable structure and configuration, such as a planar capacitor, a stack capacitor, a multi-fin capacitor, a cylinder capacitor, a trench capacitor, or a substrate-plate capacitor.

In some implementations, one or more peripheral circuits (not shown) can be coupled to the memory cell array 300A through word lines 350, bit lines 360, and any other suitable metal wirings. It is noted that the one or more peripheral circuits can include any suitable circuits for facilitating the operations of memory cell array 300A by applying and sensing voltage signals and/or current signals through word lines 350 and bit lines 360 to and from each vertical transistor 324. The one or more peripheral circuits can include various types of peripheral circuits formed using CMOS technologies.

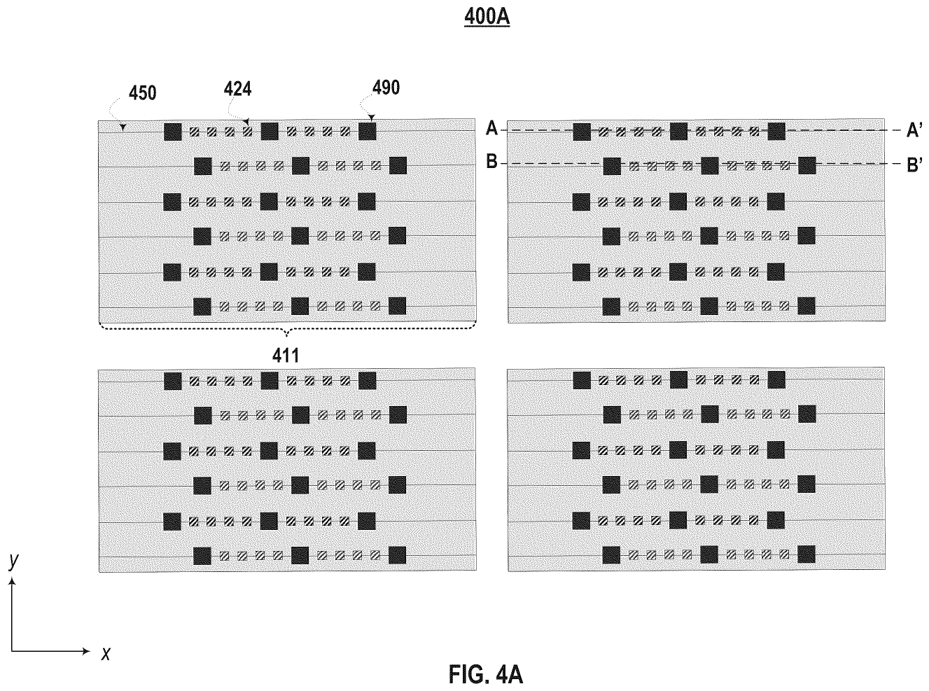

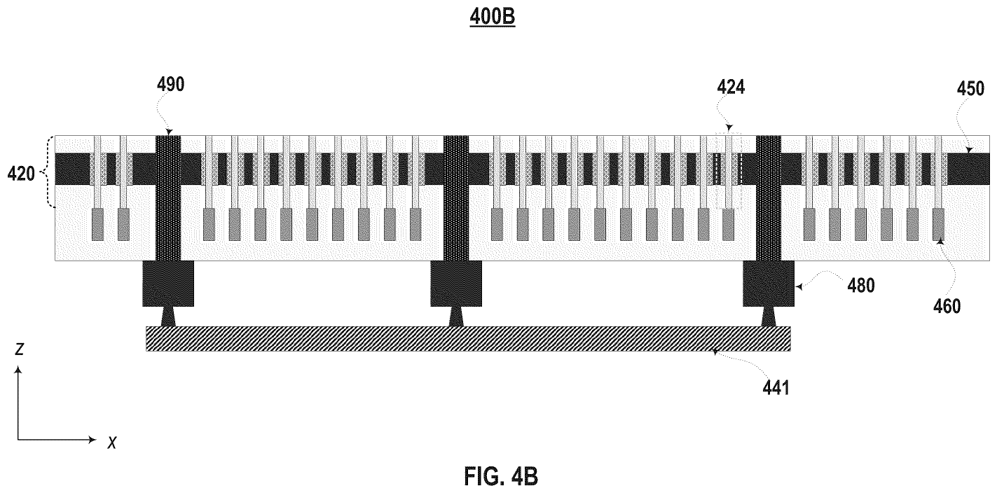

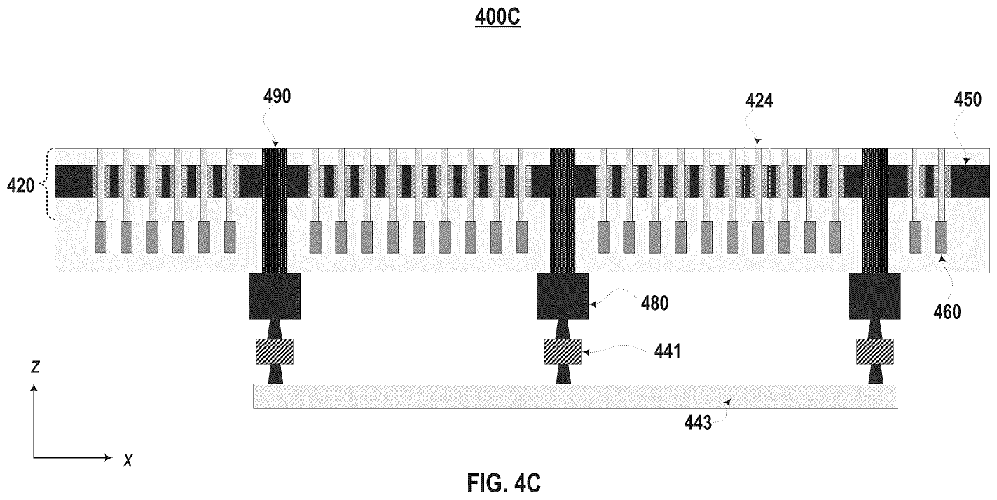

FIG. 4A illustrates a schematic plan view of a memory array 400A in the x-y plane, according to some implementations of the present disclosure. As shown in FIG. 4A, a plurality of word lines 450 extend in parallel along the first lateral direction (the x-direction), and a plurality of bit lines (not shown) extend in parallel along the second lateral direction (the y-direction). The word lines 450 and bit lines may be formed in different lateral planes for ease of routing. In some implementations, memory array 400A further comprises a plurality of word line interconnection structures 490 located within the array region and coupled with the word lines 450, and arranged in staggered columns along the second lateral direction (the y-direction).

In some implementations as shown in FIG. 4A, the plurality of word line interconnection structures 490 can be arranged as a network manner for each memory cell array 411. That is, the plurality of word line interconnection structures 490 can comprise rows of plurality of word line interconnection structures 490 aligned parallel along the first lateral direction, and columns of plurality of word line interconnection structures 490 aligned parallel along the second lateral direction. In some implementations, the word line interconnection structures 490 in a same row are connected to a same word line 450. Further, the columns of word line interconnection structures 490 can be interconnected to the corresponding word line interconnection structures 490 in a staggered manner. For example, the odd columns of word line interconnection structures 490 are connected to the odd numbers of word lines 450, respectively, while the even columns of word line interconnection structures 490 are connected to the odd numbers of word lines 450, respectively. By arranging more than one word line interconnection structures 490 for a single word line 450, the network word line interconnection structures 490 can realize a more robust word line interconnection, and a quicker word line driving effect.

FIG. 4B illustrates a schematic side cross-sectional view 400B in the x-z plane of memory array 400A shown along AA′ line, according to some implementations of the present disclosure. FIG. 4C illustrates a schematic side cross-sectional view 400C in the x-z plane of memory array 400A shown along BB′ line, according to some implementations of the present disclosure. It is noted that, the cross-sectional view 400B shown in FIG. 4B crosses an odd number of word line 450, while the cross-sectional view 400C shown in FIG. 4C crosses an even number of word line 450.

As shown in FIGS. 4B and 4C, a row of word line interconnection structures 490 along the first lateral direction (the x-direction) can be connected to a same corresponding even/odd word line 450. In the first lateral direction (the x-direction), each word line interconnection structure 490 can be located between adjacent vertical transistors 424. As described above, vertical transistors 424 can be CAA type, SMG type, DMG type, or TMG type vertical transistors. In the vertical direction (the z-direction), each word line interconnection structure 490 can extend through a layer of bit lines 460 and a transistor layer 420 comprising the vertical transistors 424, and be in contact with word line 450. A lower end of each word line interconnection structure 490 can be in contact with a conductive layer 480, such as a BEOL metal layer.

In some implementations, the odd numbers of word lines 450 and the even numbers of word lines 450 can be coupled to a same single metal layer that comprises a word line driving network. In such implementations, the single metal layer can be formed by a self-aligned double patterning (SADP) process. In some other implementations not using the SADP process, the odd numbers of word lines 450 and the even numbers of word lines 450 can be coupled to different metal layers that comprise a word line driving network. For example, the row of word line interconnection structure 490 coupled to an odd number of word line 450 as shown in FIG. 4B can be driven by a first conductive layer 441, while the row of word line interconnection structure 490 coupled to an even number of word line 450 as shown in FIG. 4C can be driven by a second conductive layer 443.

In some implementations but not shown in the figures, each memory cell of the memory cell array 411 in the disclosed memory device can further include a storage unit coupled with the vertical transistor 424. The storage unit can include any devices that can store binary data (e.g., 0 and 1), including but not limited to, capacitors for DRAM cells, and PCM elements for PCM cells. In some implementations, each vertical transistor controls the selection and/or the state switch of the respective storage unit coupled to the vertical transistor 424. In some implementations, the storage unit includes a capacitor. It is understood that the capacitor may include any suitable structure and configuration, such as a planar capacitor, a stack capacitor, a multi-fin capacitor, a cylinder capacitor, a trench capacitor, or a substrate-plate capacitor.

In some implementations, one or more peripheral circuits (not shown) can be coupled to the memory cell array 411 through word lines 450, bit lines 460, and any other suitable metal wirings. It is noted that the one or more peripheral circuits can include any suitable circuits for facilitating the operations of memory cell array 411 by applying and sensing voltage signals and/or current signals through word lines 450 and bit lines 460 to and from each vertical transistor 424. The one or more peripheral circuits can include various types of peripheral circuits formed using CMOS technologies.

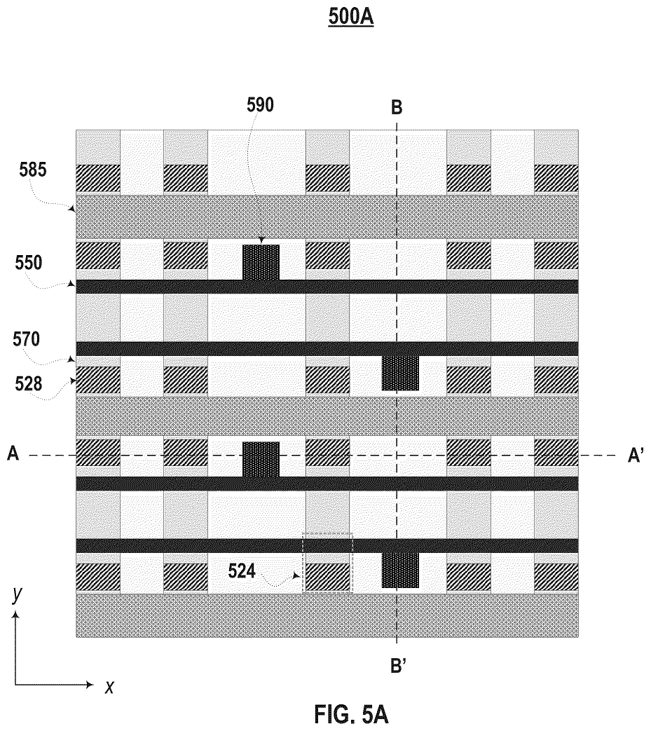

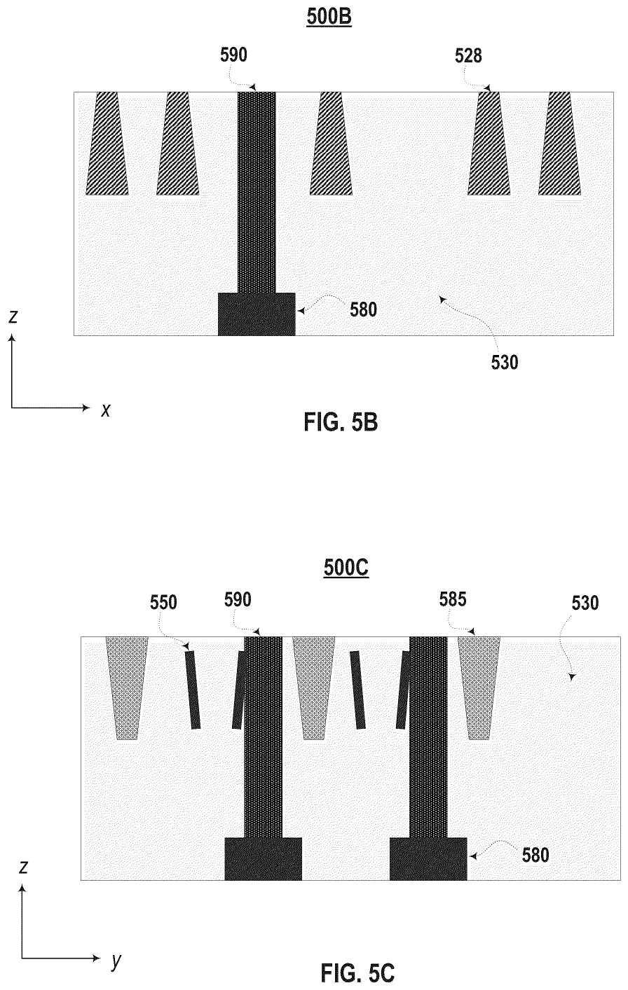

FIG. 5A illustrates a schematic plan view of a memory array 500A in the x-y plane, according to some implementations of the present disclosure. In some implementations, memory array 500A comprises an array of single-metal-gate (SMG) type vertical transistors 524. FIG. 5B illustrates a schematic side cross-sectional view 500B in the x-z plane of memory array 500A along AA′ line shown in FIG. 5A, according to some implementations of the present disclosure. FIG. 5C illustrates a schematic side cross-sectional view 500C in the y-z plane of memory array 500A along BB′ line shown in FIG. 5A, according to some implementations of the present disclosure.

As shown in FIG. 5A, a plurality of word lines 550 extend in parallel along the first lateral direction (the x-direction). Each word line 550 comprises a plurality of gate electrodes 550 of the corresponding row of vertical transistors 524 aligned along the first lateral direction. Gate electrode 550 is located at a single side of vertical semiconductor body 528 and separated from vertical semiconductor body 528 by gate dielectric 570. Every two rows of vertical transistors 524 are laterally separated by a spacer layer 585. In some implementations, spacer layer 585 can include suitable isolation materials, such as a thin insulating spacer oxide (TISO) material.

In some implementations, memory array 500A further comprises a plurality of word line interconnection structures 590 located within the array region and in contact with the word lines 550, and arranged in staggered columns along the second lateral direction (the y-direction). The word lines 550 can be interconnected to the corresponding word line interconnection structures 590 in a staggered manner. In some implementations as shown in FIG. 5A, the word line interconnection structures 590 and the vertical semiconductor bodies 528 are located on a same side of an adjacent word line 550. That is, the word line interconnection structures 590 are located between the word line 550 and the spacer layer 585 along the second lateral direction (the y-direction), and located between two vertical semiconductor bodies 528 of two adjacent vertical transistors 524 along the first lateral direction (the x-direction).

As shown in FIG. 5B, in the cross-section x-z plane, the word line interconnection structure 590 extends through insulating layer 530, and is located between vertical semiconductor body 528 of two adjacent vertical transistors 524. A lower end of word line interconnection structure 590 is in contact with a conductive layer 580 (e.g., a BEOL metal layer). As shown in FIG. 5C, in the cross-section y-z plane, the word line interconnection structure 590 is in contact with a single side of word line 550, and is located between the word line 550 and its adjacent spacer layer 585.

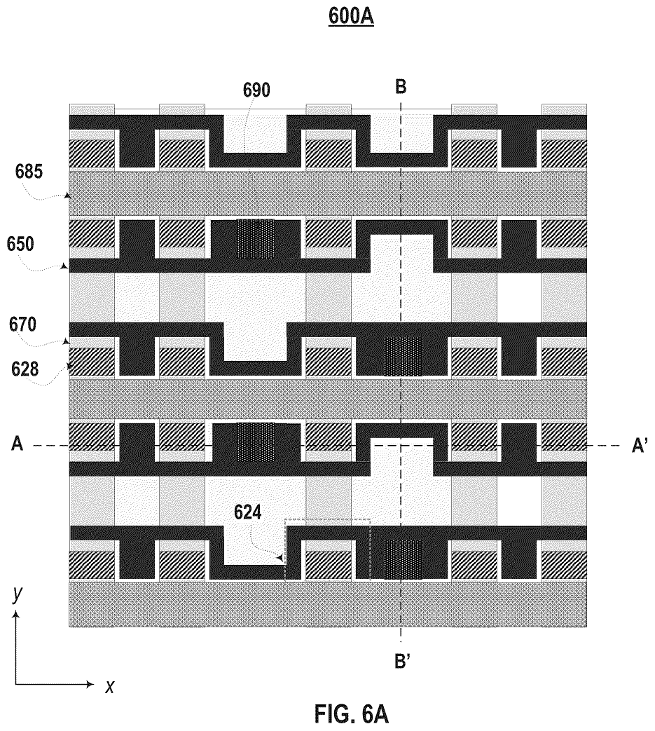

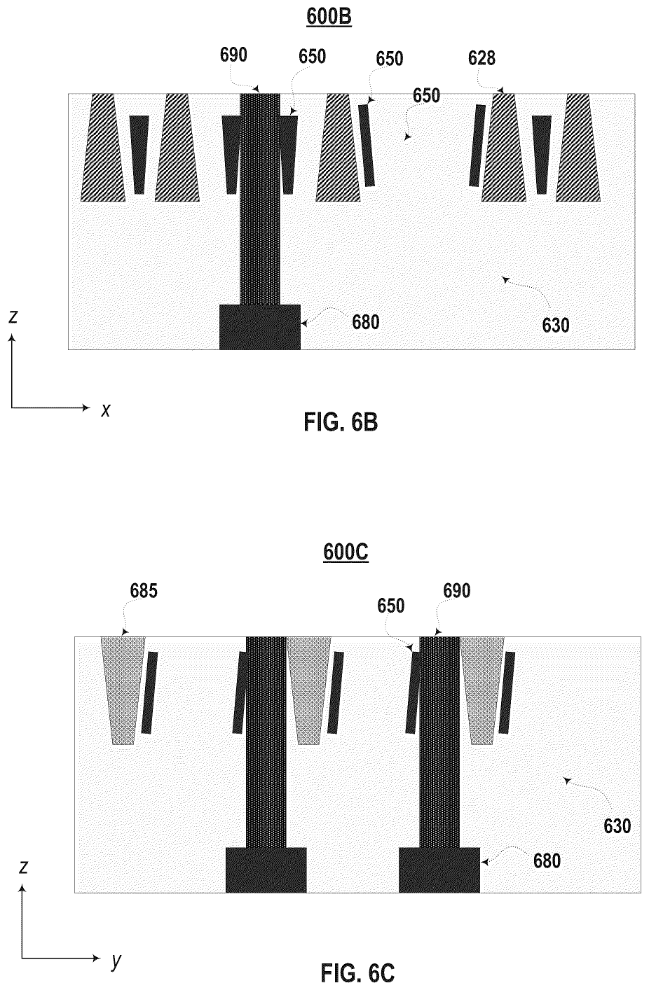

FIG. 6A illustrates a schematic plan view of a memory array 600A in the x-y plane, according to some implementations of the present disclosure. In some implementations, memory array 600A comprises an array of triple-metal-gate (TMG) type vertical transistors 624. FIG. 6B illustrates a schematic side cross-sectional view 600B in the x-z plane of memory array 600A along AA′ line shown in FIG. 6A, according to some implementations of the present disclosure. FIG. 6C illustrates a schematic side cross-sectional view 600C in the y-z plane of memory array 600A along BB′ line shown in FIG. 6A, according to some implementations of the present disclosure.

As shown in FIG. 6A, a plurality of word lines 650 extend along the first lateral direction (the x-direction). Each word line 650 comprises a plurality of gate electrodes 650 of the corresponding row of vertical transistors 624 aligned along the first lateral direction. The gate electrode 650 is located at three sides of vertical semiconductor body 628 and separated from vertical semiconductor body 628 by gate dielectric 670. Every two rows of vertical transistors 624 are laterally separated by a spacer layer 685. In some implementations, spacer layer 685 can include suitable isolation materials, such as a thin insulating spacer oxide (TISO) material.

In some implementations, memory array 600A further comprises a plurality of word line interconnection structures 690 located within the array region and in contact with the word lines 650, and arranged in staggered columns along the second lateral direction (the y-direction). The word lines 650 can be interconnected to the corresponding word line interconnection structures 690 in a staggered manner. In some implementations as shown in FIG. 6A, word line 650 partially surrounds the word line interconnection structures 690. That is, the word line interconnection structure 690 is in contact with three sides of word line 650. Further, the word line interconnection structures 690 and the vertical semiconductor bodies 628 are located on a same side of an adjacent word line 650. That is, the word line interconnection structures 690 are located between the word line 650 and the spacer layer 685 along the second lateral direction (the y-direction), and located between two vertical semiconductor bodies 628 of two adjacent vertical transistors 624 along the first lateral direction (the x-direction).

As shown in FIG. 6B, in the cross-section x-z plane, the word line interconnection structure 690 extends through insulating layer 630, is in contact with two sides of word line 650, and is located between vertical semiconductor body 628 of two adjacent vertical transistors 624. A lower end of word line interconnection structure 690 is in contact with a conductive layer 680 (e.g., a BEOL metal layer). As shown in FIG. 6C, in the cross-section y-z plane, the word line interconnection structure 690 is in contact with a third side of word line 650, and is located between the word line 650 and its adjacent spacer layer 685.

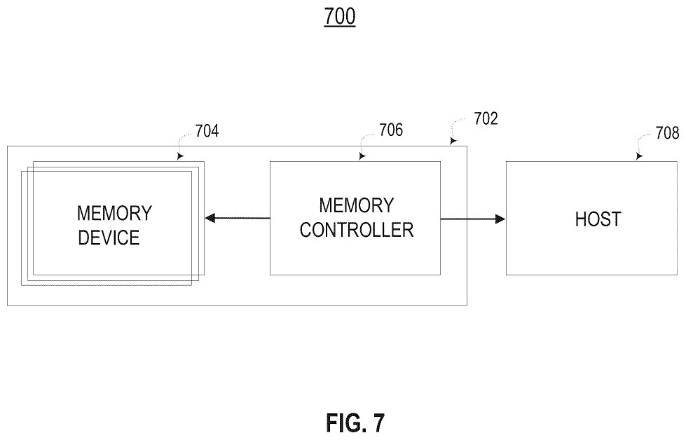

FIG. 7 illustrates a block diagram of a system 700 having a memory device, according to some implementations of the present disclosure. System 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, system 700 can include a host 708 and a memory system 702 having one or more memory devices 704 and a memory controller 706. Host 708 can be a processor of an electronic device, such as a central processing unit (CPU), or a system-on-chip (SoC), such as an application processor (AP). Host 708 can be configured to send or receive the data to or from memory devices 704. Memory device 704 can be any memory devices disclosed herein, such as memory device 100. In some implementations, memory device 704 includes one or more arrays of memory cells shown in 200A/200B/300A/400A/500A/600A, as described above in detail.

Memory controller 706 is coupled to memory device 704 and host 708 and is configured to control memory device 704, according to some implementations. Memory controller 706 can manage the data stored in memory device 704 and communicate with host 708. Memory controller 706 can be configured to control operations of memory device 704, such as read, write, and refresh operations. Memory controller 706 can also be configured to manage various functions with respect to the data stored or to be stored in memory device 704 including, but not limited to refresh and timing control, command/request translation, buffer and schedule, and power management. In some implementations, memory controller 706 is further configured to determine the maximum memory capacity that the computer system can use, the number of memory banks, memory type and speed, memory particle data depth and data width, and other important parameters. Any other suitable functions may be performed by memory controller 706 as well. Memory controller 706 can communicate with an external device (e.g., host 708) according to a particular communication protocol. For example, memory controller 706 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

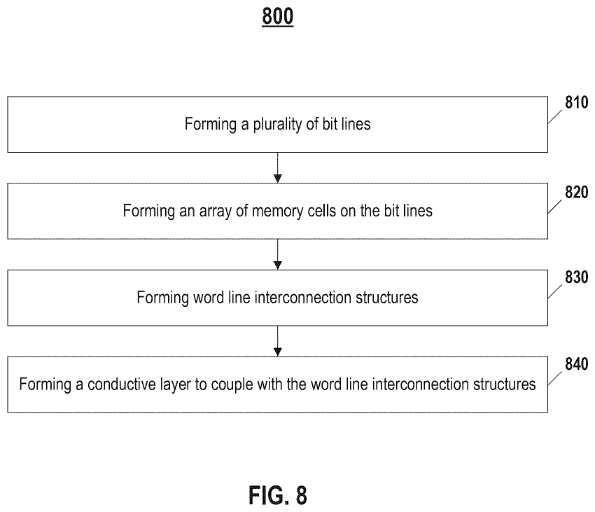

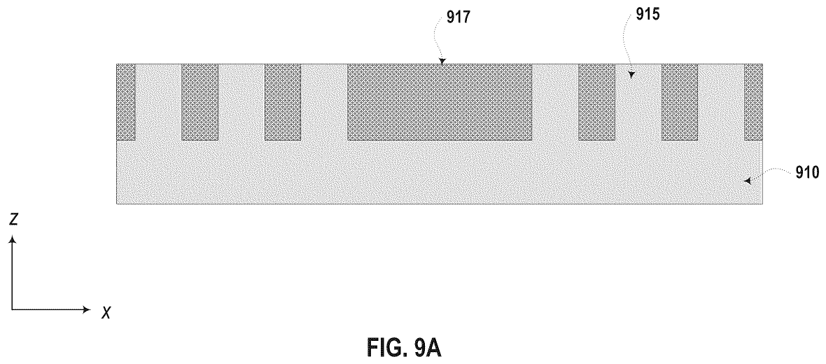

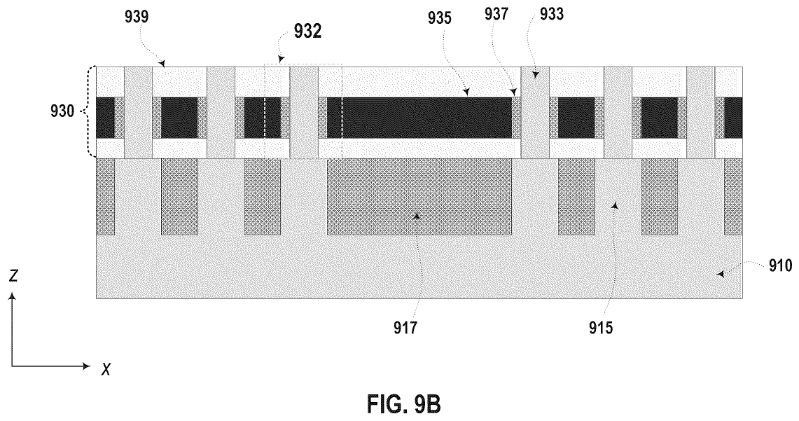

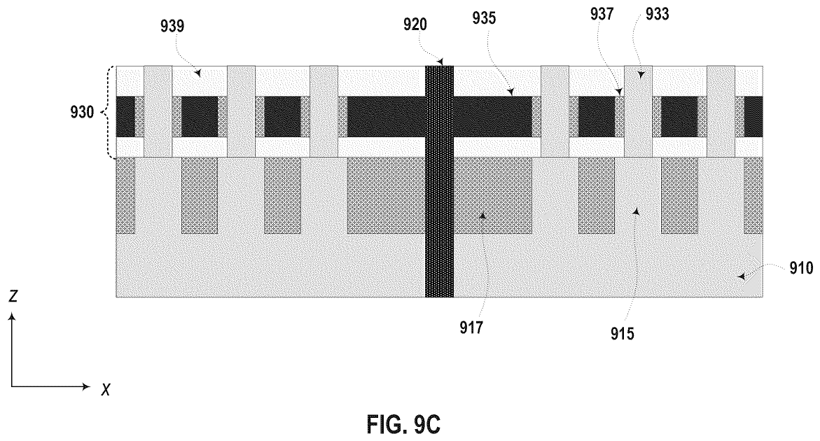

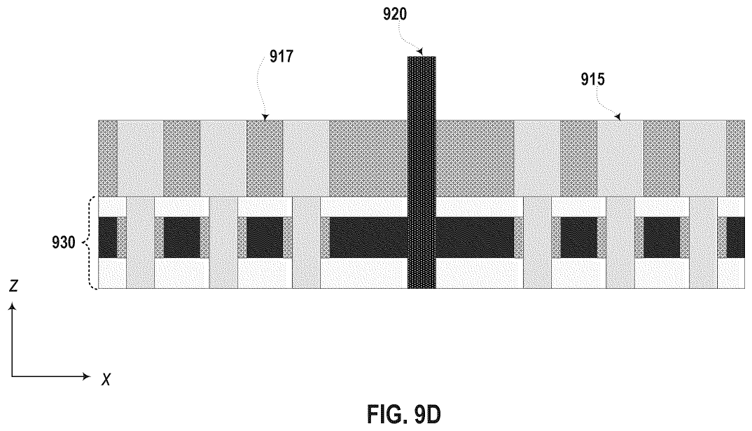

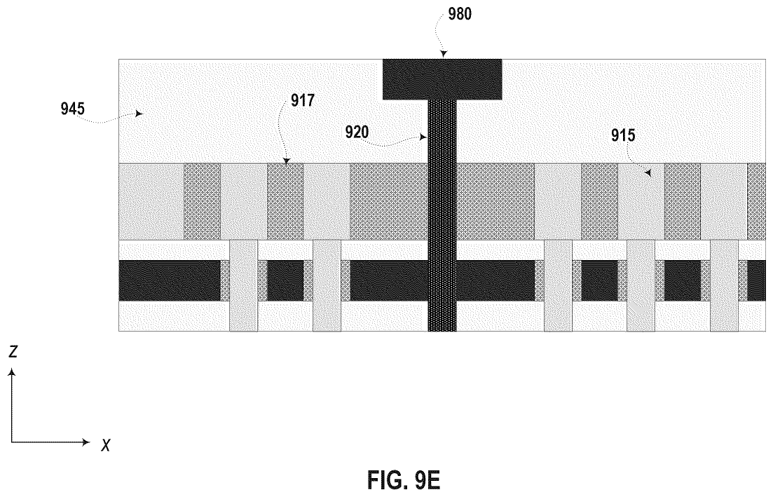

FIG. 8 illustrates a flowchart of a fabricating method 800 for forming a 3D memory device, according to some implementations of the present disclosure. FIGS. 9A-9E illustrate schematic side cross-sectional views of a 3D memory device at certain fabricating stages of the method 800 shown in FIG. 8, according to various implementations of the present disclosure. It is understood that the operations shown in method 800 are not exhaustive and that other operations can be performed as well before, after, or between any of the illustrated operations. Further, some of the operations may be performed simultaneously, or in a different order than shown in FIG. 8.

As shown in FIG. 8, method 800 can start at operation 810, in which a plurality of bit lines can be formed. FIG. 9A illustrates a schematic side cross-sectional view of the 3D memory device in the x-z plane after operation 810 of method 800.

As shown in FIG. 9A, a plurality of bit lines 915 can be formed on a substrate 910. In some implementations, substrate 910 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In such implementations, the plurality of bit lines 915 can be formed by a patterning process (e.g., photoetching, dry etching, wet etching, cleaning, chemical mechanical polishing (CMP), etc., to remove portions of substrate 910 to form parallel trenches each extending in the second lateral direction (the y-direction). The trenches can then be filled with any suitable insulating material including, but not limited to, silicon oxide, silicon nitride, silicon oxynitride, low-k dielectrics, or any combination thereof, by using a deposition process to form spacers 917. The protruding portions of substrate 910 laterally separated by spacers 917 can form the plurality of bit lines 915, parallelly arranged in the first lateral direction (the x-direction), each extending along the second lateral direction (the y-direction).

Referring back to FIG. 8, method 800 can proceed to operation 820, in which an array of memory cells can be formed on the bit lines. FIG. 8B illustrates a schematic side cross-sectional view of the 3D memory device in the x-z plane after operation 820 of method 800.

As shown in FIG. 9B, forming the array of memory cells can include forming a transistor layer 930 comprising an array of vertical transistors 932. Forming the transistor layer 930 can include forming a plurality of vertical semiconductor pillars 933 each penetrating an insulating layer 939. Each column of vertical semiconductor pillars 933 along the second lateral direction (the y-direction) can be in contact with a corresponding same bit line 915. In some implementations, vertical semiconductor pillars 933 can include any suitable semiconductor material, such as polycrystalline silicon. Vertical semiconductor pillars 933 can have a leakage value lower than a pico-ampere. In some implementations, the leakage value of vertical semiconductor pillars 933 is lower than the intrinsic leakage value of monocrystalline silicon. In some implementations, a material of vertical semiconductor pillars 933 can be a metal oxide semiconductor material, such as IGZO.

As shown in FIG. 9B, forming transistor layer 930 can further include forming gate electrodes 935 at one or more lateral sides of vertical semiconductor pillars 933, and forming gate dielectric layer 937 between gate electrodes 935 and vertical semiconductor pillars 933. In some implementations, gate electrodes 935 of each row of vertical transistors 932 along the first lateral direction (x-direction) can be connected with each other to form one word line 935. Gate electrodes 935 can include any suitable conductive materials, such as polysilicon, metals (e.g., W, Cu, Al, etc.), metal compounds (e.g., TiN, TaN, etc.), or silicides. For example, gate electrode 935 may include doped polysilicon, i.e., gate poly. In some implementations, gate electrode 935 includes multiple conductive layers, such as a W layer over a TiN layer. Gate dielectric layer 937 can include any suitable dielectric materials, such as silicon oxide, silicon nitride, silicon oxynitride, or high-k dielectrics. For example, gate dielectric layer 937 may include silicon oxide, i.e., gate oxide. In some implementations, gate electrodes 935 and gate dielectric layer 937 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc.).

Although not shown in FIG. 9B, forming the array of memory cells can further include forming a storage unit layer including an array of storage units each coupled with a corresponding one of the array of vertical transistors 932. In some implementations, the array of storage units can be an array of capacitors including a common second electrode, a plurality of first electrode, and a capacitor dielectric layer between the first electrodes and the common second electrode. In some implementations, the first electrodes and/or the common second electrode can include conductive materials including, but not limited to, W, Co, Cu, Al, TiN, TaN, polysilicon, silicides, or any combination thereof. In some implementations, the capacitor dielectric layer includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the array of capacitors can be formed by a series of fabricating processes including thin film deposition processes (e.g., CVD, PVD, ALD, etc.) and patterning processes (e.g., photoetching, dry etching, wet etching, cleaning, CMP, etc.).

Referring back to FIG. 8, method 800 can proceed to operation 830, in which word line interconnection structures can be formed. FIG. 9C illustrates a schematic side cross-sectional view of the 3D memory device in the x-z plane at a certain stage of operation 830 of method 800.

As shown in FIG. 9C, a plurality of word line interconnect structures 920 can be formed to penetrate transistor layer 930 and spacer 917, and to extend into substrate 910. In some implementations, the plurality of word line interconnect structures 920 can be formed by removing portions of word lines 935 and substrate 910 to form openings, each vertically extending through word lines 935 and spacer 917 into substrate 910, and filling the openings with a conductive material. In some implementations, the plurality of word line interconnect structures 920 can be formed in the array region, and be arranged in staggered columns along the second lateral direction (the y-direction). In some implementations, a first column of word line interconnect structures 920 aligned along the second lateral direction can be connected to the odd numbers of word lines 935, respectively, while a second column of word line interconnect structures 920 aligned along the second lateral direction can be connected to the even numbers of word lines 935, respectively. In some implementations, word line interconnection structures 920 can include any suitable conductive materials, such as polysilicon, metals (e.g., W, Cu, Al, etc.), metal compounds (e.g., TiN, TaN, etc.), or silicides. In some implementations, word line interconnection structures 920 can include multiple conductive layers, such as a W layer over a TiN layer.

In some other implementations, forming the word line interconnect structures 920 can include forming a plurality of sacrificial interconnects, and then replacing the plurality of sacrificial interconnects with conductive word line interconnect structures 920. For example, a plurality of sacrificial interconnects (not shown) can be formed by removing portions of word lines 935, insulating layer 939, spacer 917, and substrate 910 to form openings, each vertically extending through word lines 935 into substrate 910, and filling the openings with a sacrificial material. And the sacrificial material can be replaced from the backside of substrate 910 in a subsequent process.

Referring back to FIG. 8, method 800 can proceed to operation 840, in which a conductive layer can be formed to couple with the word line interconnection structures. FIGS. 9D and 9E each illustrates a schematic side cross-sectional view of the 3D memory device in an x-z plane at a certain stage of operation 840 of method 800.

In some implementations, the 3D structure shown in FIG. 9C can be flipped over. Portions of substrate 910 can be removed by any suitable process, such as dry etching, wet etching, CMP, etc., to expose the word line interconnect structures 920. As shown in FIG. 9D, portions of substrate 910 can be further removed by any suitable process, such as dry etching, wet etching, CMP, etc., to expose portions of the spacer 917 and bit lines 915. As shown in FIG. 9E, an insulating layer 945 can be formed to cover exposed surfaces of bit lines 915. In some implementations, insulating layer 945 can include any suitable dielectric material including, but not limited to, silicon oxide, silicon nitride, silicon oxynitride, low-k dielectrics, or any combination thereof. A conductive layer 980 can be formed in insulating layer 945 and in contact with word line interconnection structures 920. In some implementations, conductive layer 980 can include one or more BEOL metal layers, and can be formed by any suitable series of fabricating processes including thin film deposition processes (e.g., CVD, PVD, ALD, etc.) and patterning processes (e.g., photoetching, dry etching, wet etching, cleaning, CMP, etc.).

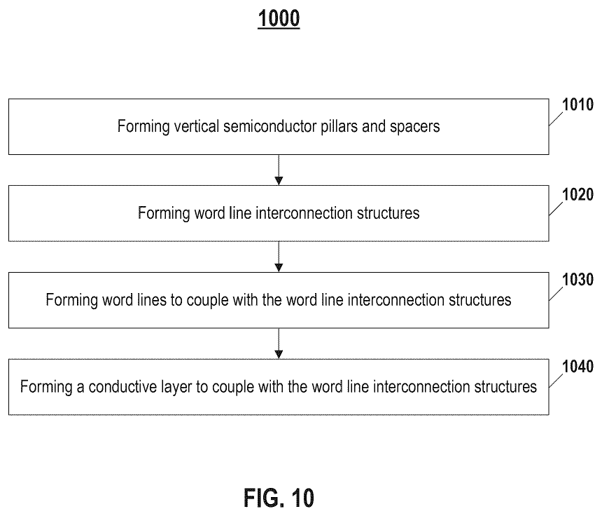

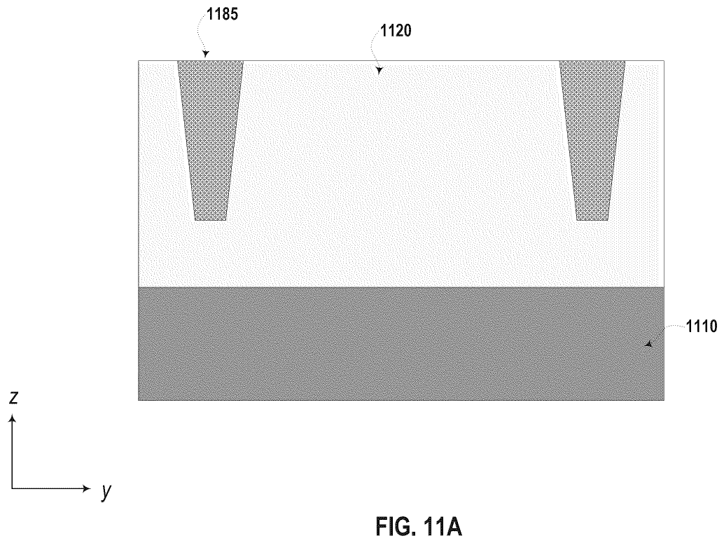

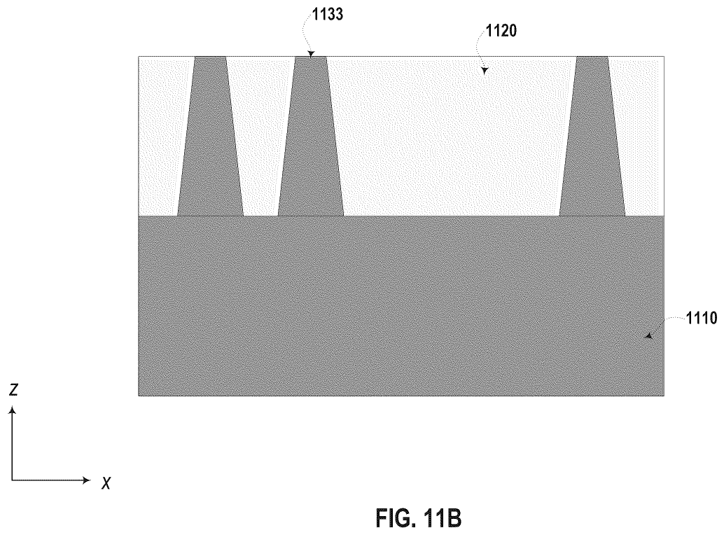

FIG. 10 illustrates a flowchart of a fabricating method 1000 for forming a 3D memory device, according to some implementations of the present disclosure. FIGS. 11A-11B, 12A-12B, 13, and 14 illustrate schematic side cross-sectional views of a 3D memory device at certain fabricating stages of the method 1000 shown in FIG. 10, according to various implementations of the present disclosure. It is understood that the operations shown in method 1000 are not exhaustive and that other operations can be performed as well before, after, or between any of the illustrated operations. Further, some of the operations may be performed simultaneously, or in a different order than shown in FIG. 10.

As shown in FIG. 10, method 1000 can start at operation 1010, in which a plurality of vertical semiconductor pillars and spacers can be formed. FIG. 11A illustrates a schematic side cross-sectional view of the 3D memory device in the y-z plane after operation 1010 of method 1000. FIG. 11B illustrates a schematic side cross-sectional view of the 3D memory device in the x-z plane after operation 1010 of method 1000.

As shown in FIGS. 11A and 11B, a plurality of a plurality of vertical semiconductor pillars 1133 can be formed on a substrate 1110. In some implementations, the vertical semiconductor pillars 1133 can be arranged in an array in the lateral plane. In some implementations, substrate 1110 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In some implementations, the plurality of spacers 1185 can be arranged in parallel each extending in the first lateral direction (the x-direction).

In such implementations, the plurality of vertical semiconductor pillars 1133 and spacers 1185 can be formed by a patterning process (e.g., photoetching, dry etching, wet etching, cleaning, chemical mechanical polishing (CMP), etc., to remove portions of substrate 1110 to form trenches each extending in the first lateral direction (the x-direction) and the second lateral direction (the y-direction). An insulating layer 1120 can be formed to fill the trenches. Portions of the protruding portions of substrate 1110 can be further removed and filled with a thin insulating spacer oxide (TISO) material to form the spacers 1185. The remaining portions of the substrate 1110 laterally separated by insulating layer 1120 and spacers 1185 can form the plurality of vertical semiconductor pillars 1133.

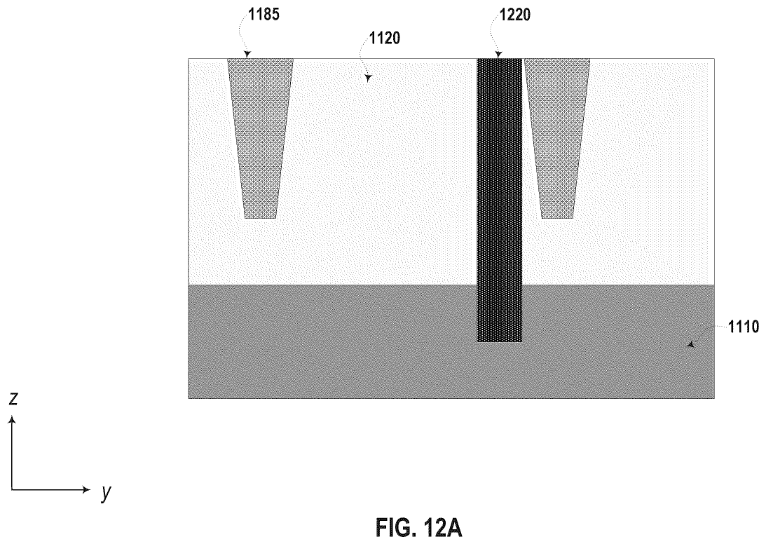

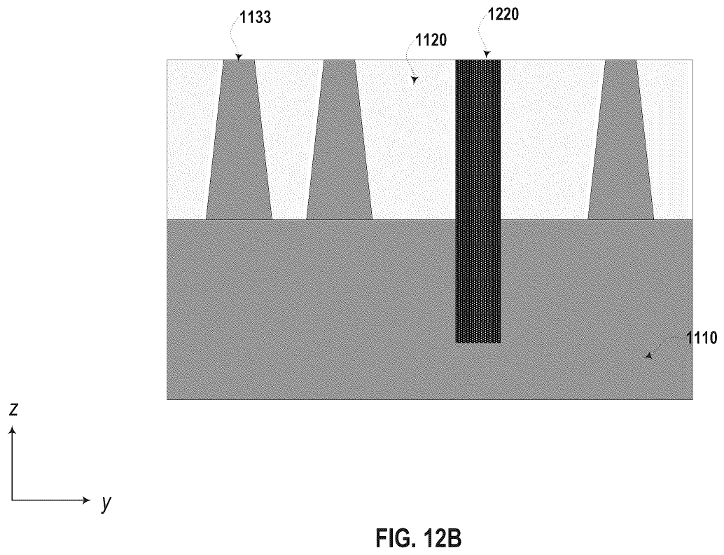

As shown in FIG. 10, method 1000 can proceed to operation 1020, in which word line interconnection structures can be formed. FIG. 12A illustrates a schematic side cross-sectional view of the 3D memory device in the y-z plane after operation 1020 of method 1000. FIG. 12B illustrates a schematic side cross-sectional view of the 3D memory device in the x-z plane after operation 1020 of method 1000.

As shown in FIGS. 12A and 12B, a plurality of word line interconnect structures 1220 can be formed to penetrate insulating layer 1120 and to extend into substrate 1110. In some implementations, the plurality of word line interconnect structures 1220 can be formed by removing portions of insulating layer 1120 and substrate 1110 to form openings, each vertically extending through insulating layer 1120 into substrate 1110, and filling the openings with a conductive material. In some implementations, the plurality of word line interconnect structures 1220 can be formed in the array region, and be arranged in staggered columns along the second lateral direction (the y-direction). In some implementations, word line interconnection structures 920 can include any suitable conductive materials, such as polysilicon, metals (e.g., W, Cu, Al, etc.), metal compounds (e.g., TiN, TaN, etc.), or silicides. In some implementations, word line interconnection structures 920 can include multiple conductive layers, such as a W layer over a TiN layer.

In some other implementations, forming the word line interconnect structures 1220 can include forming a plurality of sacrificial interconnects, and then replacing the plurality of sacrificial interconnects with conductive word line interconnect structures 1220. For example, a plurality of sacrificial interconnects (not shown) can be formed by removing portions of insulating layer 1120 and substrate 1110 to form openings, each vertically extending through insulating layer 1120 into substrate 1110, and filling the openings with a sacrificial material. And the sacrificial material can be replaced from the backside of substrate 1110 in a subsequent process.

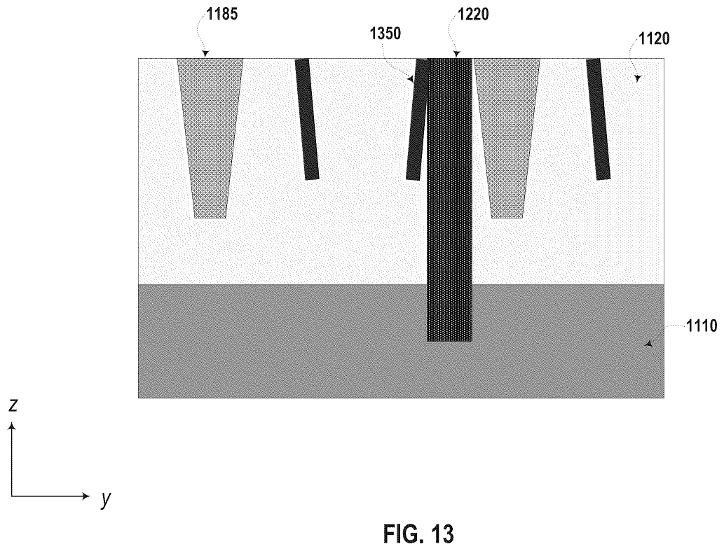

Referring back to FIG. 10, method 1000 can proceed to operation 1030, in which a plurality of word lines can be formed to couple with the word line interconnection structures. FIG. 13 illustrates a schematic side cross-sectional view of the 3D memory device in the y-z plane after operation 1030 of method 1000.

As shown in FIG. 13, a plurality of word lines 1350 can be formed in contact with the word line interconnect structures 1220. In some implementations, each word line 1350 can be formed at one or more lateral sides of a row of vertical semiconductor pillars 1133. In some implementations, word lines 1350 can include any suitable conductive materials, such as polysilicon, metals (e.g., W, Cu, Al, etc.), metal compounds (e.g., TiN, TaN, etc.), or silicides. For example, word lines 1350 may include doped polysilicon, i.e., gate poly. In some implementations, word lines 1350 includes multiple conductive layers, such as a W layer over a TiN layer. In some implementations, word lines 1350 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc.). In some implementations, the odd numbers of word lines 1350 can be formed to contact with a first column of word line interconnect structures 1220 aligned along the second lateral direction, respectively, while the even numbers of word lines 1350 can be formed to contact with a second column of word line interconnect structures 920 aligned along the second lateral direction, respectively.

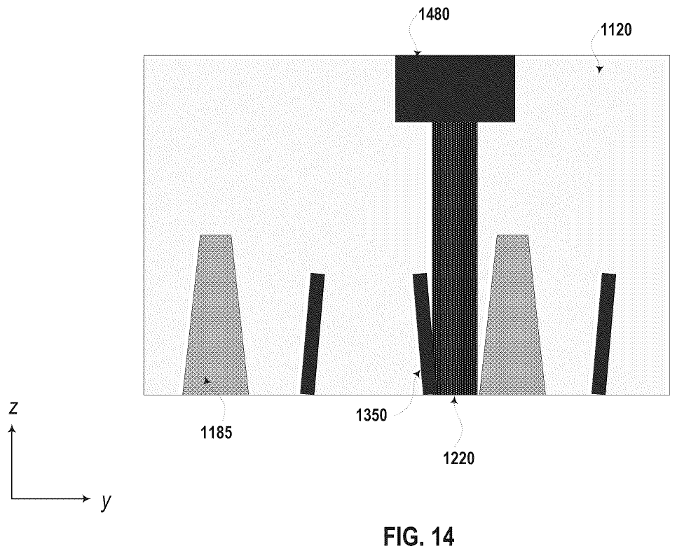

Referring back to FIG. 10, method 1000 can proceed to operation 1040, in which a conductive layer can be formed to couple with the word line interconnection structures. FIG. 14 illustrates a schematic side cross-sectional view of the 3D memory device in x-z plane after operation 1040 of method 1000.

In some implementations, the 3D structure shown in FIG. 13 can be flipped over. Portions of substrate 1110 can be removed by any suitable process, such as dry etching, wet etching, CMP, etc., to expose the word line interconnect structures 1220. As shown in FIG. 9E, a conductive layer 1480 can be formed in insulating layer 1120 and in contact with word line interconnection structures 1220. In some implementations, conductive layer 1480 can include one or more BEOL metal layers, and can be formed by any suitable series of fabricating processes including thin film deposition processes (e.g., CVD, PVD, ALD, etc.) and patterning processes (e.g., photoetching, dry etching, wet etching, cleaning, CMP, etc.).

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations, but should be defined only in accordance with the following claims and their equivalents.

What is claimed is:

1. A memory device, comprising:
an array of memory cells in an array region;
word lines extending parallel in a first lateral direction;
bit lines extending parallel in a second lateral direction; and
interconnection structures located within the array region and coupled with the word lines, and arranged in staggered columns along the second lateral direction.

2. The memory device of claim 1, wherein:
a first distance between two interconnection structures coupled with two adjacent word lines is greater than a second distance between the two adjacent word lines.

3. The memory device of claim 1, wherein:
a first column of interconnection structures are located at a first side of a center position of the array region; and
a second column of interconnection structures are located at a second side of the center position opposite to the first side.

4. The memory device of claim 1, wherein:
a first column of interconnection structures are located at a first side of one bit line; and
a second column of interconnection structures are located at a second side of the one bit line opposite to the first side.

5. The memory device of claim 1, further comprising:
a conductive layer connected to first ends of the interconnection structures,
wherein second ends of the interconnection structures are connected to the word lines.

6. The memory device of claim 1, wherein:
the interconnection structures comprise rows of interconnection structures aligned parallel along the first lateral direction; and
the interconnection structures in a same row are connected to a same word line.

7. The memory device of claim 6, further comprising:
a first conductive layer connected to odd numbers of rows of interconnection structures; and
a second conductive layer connected to even numbers of rows of interconnection structures.

8. The memory device of claim 1, wherein:
each of the array of memory cells comprises a vertical transistor and a storage unit coupled with the vertical transistor; and
each word line comprises gate structures of a corresponding row of vertical transistors aligned along the first lateral direction;
wherein in each vertical transistor, a gate structure is located at a lateral side of a channel structure of the vertical transistor.

9. The memory device of claim 8, wherein in each vertical transistor, the gate structure is located at three lateral sides of the channel structure of the vertical transistor.

10. The memory device of claim 8, wherein in each vertical transistor, the gate structure laterally surrounds the channel structure of the vertical transistor.

11. A method of forming a memory device, comprising:
forming bit lines extending parallel in a second lateral direction on a semiconductor layer;
forming an array of vertical transistors, comprising:
forming an array of vertical channel structures, each column of the vertical channel structures along the second lateral direction are coupled with a corresponding one of the bit lines, and
forming gates structures at a lateral side of each row of the vertical channel structures along a first lateral direction, wherein the gates structures of each column of the array of vertical transistors form one word line along the first lateral direction;
forming interconnection structures each vertically extending through the semiconductor layer and in contact with a corresponding word line;
removing the semiconductor layer to expose portions of the interconnection structures; and
forming a conductive layer coupled with the interconnection structures.

12. The method of claim 11, wherein:
forming the interconnection structures comprises forming columns of interconnection structures aligned parallel along the second lateral direction; and
adjacent columns of interconnection structures are arranged in a staggered form.

13. The method of claim 11, wherein:
forming the interconnection structures comprises forming rows of interconnection structures aligned parallel along the first lateral direction; and
the interconnection structures in a same row are connected to a same word line, and adjacent rows of interconnection structures are arranged in a staggered form.

14. The method of claim 13, wherein forming the conductive layer comprises:
forming a first conductive layer connected to odd numbers of rows of interconnection structures; and
forming a second conductive layer connected to even numbers of rows of interconnection structures.

15. The method of claim 11, further comprising:
forming an array of storage units on the array of vertical transistors.

16. A method of forming a memory device, comprising:
forming an array of semiconductor pillars on a semiconductor layer;
forming an insulating layer on the semiconductor layer to laterally isolate the semiconductor pillars;
forming sacrificial structures each vertically extending through the insulating layer and into the semiconductor layer;
forming conductive lines each at a lateral side of each row of the semiconductor pillars along a first lateral direction, wherein the conductive lines are in contact with the sacrificial structures;
removing the semiconductor layer to expose portions of the sacrificial structures;
replacing the sacrificial structures with interconnection structures; and
forming a conductive layer coupled with the interconnection structures.

17. The method of claim 16, wherein:
forming the sacrificial structures comprises forming columns of sacrificial structures aligned parallel along a second lateral direction; and
adjacent columns of sacrificial structures are arranged in a staggered form.

18. The method of claim 16, wherein:
forming the sacrificial structures comprises forming rows of sacrificial structures aligned parallel along the first lateral direction; and
the sacrificial structures in a same row are connected to a same conductive line, and adjacent rows of sacrificial structures are arranged in a staggered form.

19. The method of claim 16, wherein forming the conductive layer comprises:
forming a first conductive layer connected to odd numbers of rows of interconnection structures; and
forming a second conductive layer connected to even numbers of rows of interconnection structures.

20. The method of claim 17, further comprising:
forming bit lines and extending parallel in the second lateral direction and coupled with second ends of the array of semiconductor pillars; and
forming an array of storage units coupled with second ends of the array of semiconductor pillars.
